(19) United States
(12) Patent Application Publication
(10) Pub. No.: US 2008/0186685 A1
(43) Pub. Date: Aug. 7, 2008

(54) PRINTED CIRCUIT BOARD AND SEMICONDUCTOR MEMORY MODULE USING THE SAME

(75) Inventors: Jung-Chan CHO, Chungcheongnam-do (KR); Hyun-Seok CHOI, Chungcheongnam-do (KR); Yong-Hyun KIM, Gyeonggi-do (KR); Hyung-Mo HWANG, Chungcheongnam-do (KR); Kyu-Tae KIM, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/013,245

(22) Filed: Jan. 11, 2008

(30) Foreign Application Priority Data
Feb. 6, 2007 (KR) 10-2007-12206

(51) Int. Cl. H05K 1/14; H05K 1/02; H05K 7/20

(52) U.S. Cl. 361/737; 174/255; 361/715

(57) ABSTRACT

The invention provides a semiconductor memory module. The semiconductor memory module includes a printed circuit board part having a first surface and a second surface facing the first surface, and a metal core having an insert part inserted inside the printed circuit board part and an extension part elongated from at least one side of the printed circuit board. The semiconductor memory module also includes memory parts mounted on the printed circuit board. The metal core has a folding structure having at least one bent portion to substantially cover the memory parts.

### CROSS-REFERENCE TO RELATED APPLICATIONS

This U.S. non-provisional patent application claims priority under 35 U.S.C. §119 to Korean Patent Application No. 10-2007-12206 filed on Feb. 6, 2007, the entire contents of which are hereby incorporated by reference.

### BACKGROUND

The present invention relates to a semiconductor device, and more specifically to a semiconductor memory module.

Generally, semiconductor memory modules refer to a product for expanding the memory storage capacity in electric circuit systems such as personal computers and mass storage workstations. A semiconductor memory module has a structure that has multiple semiconductor memory chips mounted in one printed circuit board (PCB).

As the electronics industry has developed, semiconductor memory modules have continued to be scaled down and while having a higher performance. However, while consumer demand for semiconductor memory module storage capacity is rapidly increasing from the development and continued spread of the internet and computerization of business, capacity-expanding technology of the semiconductor memory module is reaching its limit with the current conventional technology. Accordingly, the demand for semiconductor memory modules able to meet consumer requirements is rapidly rising.

FIG. 1A is a perspective view of a conventional semiconductor memory module, and FIG. 1B is a top plan view of FIG. 1A.

Referring to FIG. 1A and FIG. 1B, a semiconductor memory module may include a printed circuit board (PCB) 10 and memory parts 20. The PCB 10 may be a rigid PCB or a flexible PCB. The memory parts 20 may be semiconductor memory chips or semiconductor memory packages.

When the PCB 10 is inserted in a connector unit of a main board in an electronic circuit system such as a personal computer or a workstation, connector connecting pins 12 may be included, where the connector connecting pins 12 are typically provided on one edge of the PCB 10, for electrically connecting the PCB 10 with the memory parts 20 to the main board. The memory parts 20 may be mounted on a first surface or on a second surface facing the first surface of the PCB 10 with the mounting means 25.

As the memory chips used for increasing the memory storage capacity of the semiconductor memory module are scaled down or are increasingly required to run at higher operation speeds for high-performance, heat produced from the operation of the semiconductor memory module may increase. The heat may lower the operation characteristics or reliability of the semiconductor memory module. The above conventional semiconductor memory module, however, has a structure that does not effectively emit the heat produced during operation, which causes problems of lowering the operation characteristics and reliability of the semiconductor memory module.

### SUMMARY OF THE INVENTION

Exemplary embodiments of the present invention are directed to a printed circuit board and a semiconductor memory module using the same. In an exemplary embodiment, the printed circuit board may comprise a printed circuit board part having a first surface and a second surface facing the first surface, and a metal core having an insert part inserted inside the printed circuit board part and having an extension part elongated from at least one side of the printed circuit board part, wherein the metal core has a folding structure having at least one bent portion.

In another exemplary embodiment, a semiconductor memory module may comprise a printed circuit board including a printed circuit board part having a first surface and a second surface facing the first surface, a metal core having an insert part inserted inside the printed circuit board part and having an extension part elongated from at least one side of the printed circuit board, and memory parts mounted on the printed circuit board, wherein the metal core has a folding structure having at least one bend portion to cover the memory parts.

### BRIEF DESCRIPTION OF THE DRAWINGS

FIG. 1A is a perspective view of a conventional semiconductor memory module, and FIG. 1B is a top plan view of FIG. 1A;

FIG. 2A is a perspective view of a semiconductor memory module according to an exemplary embodiment of the present invention, and FIG. 2B and FIG. 2C are a top plan view and a side view of FIG. 2A, respectively;

FIG. 3A is a perspective view of a semiconductor memory module according to another exemplary embodiment of the present invention, and FIG. 3B and FIG. 3C are a top plan view and a side view of FIG. 3A, respectively; and

FIGS. 4 to 8 are side views of semiconductor memory modules according to other exemplary embodiments of the present invention.

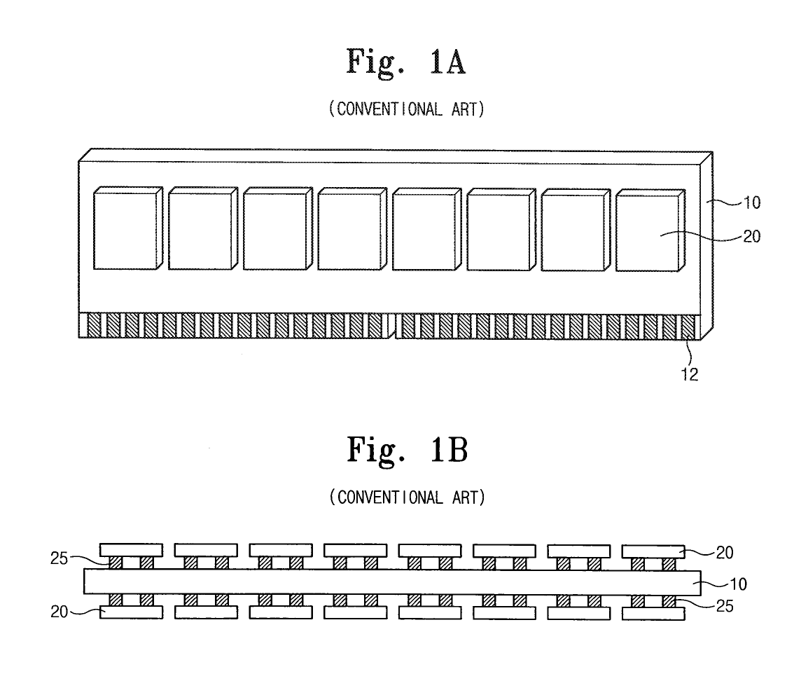

### DETAILED DESCRIPTION OF PREFERRED EMBODIMENTS

The present invention will now be described more fully hereinafter with reference to the accompanying drawings, in which exemplary embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like numbers refer to like elements throughout.

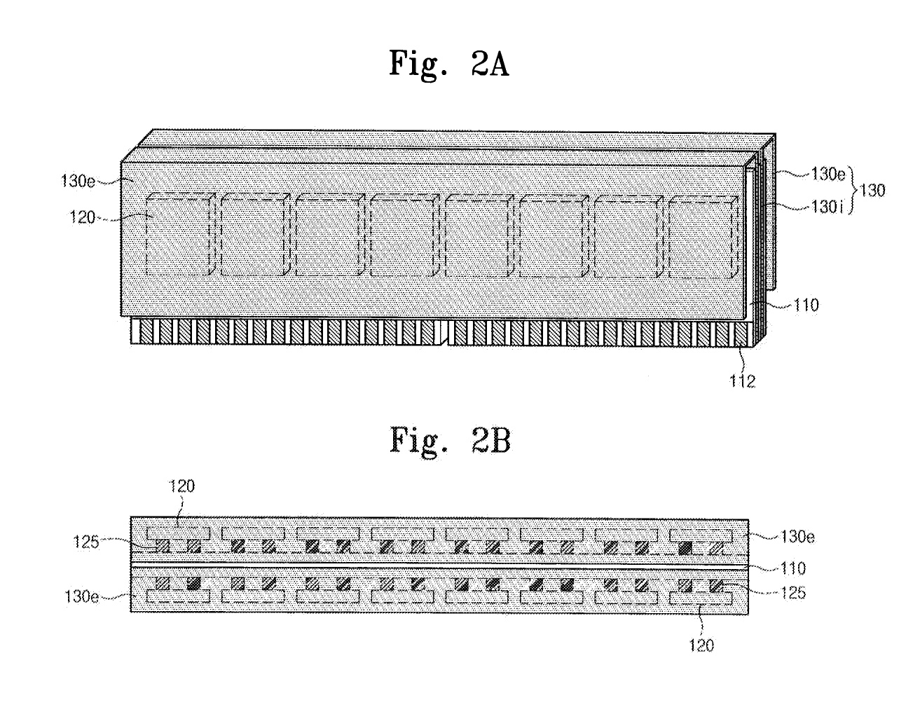

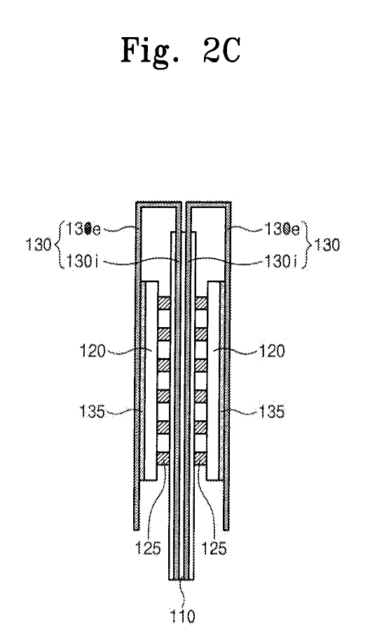

FIG. 2A is a perspective view of a semiconductor memory module according to an exemplary embodiment of the present invention, and FIG. 2B and FIG. 2C are a top plan view and a side view of FIG. 2A, respectively.

Referring to FIG. 2A to FIG. 2C, the semiconductor memory module may include a printed circuit board (PCB) and memory parts.

The PCB may include a PCB part 110 having a first surface and a second surface facing the first surface, and a metal core 130 having an insert part 130i inserted inside the PCB part 110 and an elongated extension part 130e extending from one side of the PCB part 110. As illustrated in FIG. 2A, the elongated extension part 130e may extend from a side of the PCB part 110 in the short axis direction. The extension part 130e of the metal core 130 may have a folding structure having at least one bent portion so that the extension part 130e substantially covers the memory parts 120. Thus, the extension part 130e of the metal core 130 may be elongated from a side of the PCB part 110 in the short axis direction and include a bent structure so as to be folded over and substantially cover the memory parts 120.

The PCB part 110 may be a rigid PCB or a flexible PCB. The metal core 130 may include thermal conductive material. The thermal conductive material may include one or more materials selected from the group consisting of aluminum (Al), copper (Cu), silver (Ag), and gold (Au). However, the thermal conductive material may also include various other materials known in the art that either aid in the thermal conducting or aid in the structural integrity of the metal core 130. The metal core 130 may act as a heat sink whereby it serves as a passage for emitting heat produced during the operation of the semiconductor memory module. That is, since high operating temperatures reduce the performance of the memory parts 120 in a memory module as well as affecting the overall performance of the memory module, it is desirable to remove at least some of the heat produced during operation of the memory module away from the memory parts 120 and memory module to prevent the operating temperatures from drastically increasing and thereby reducing the overall performance of the memory module. In this embodiment of the present invention, the insert part 130i of the metal core 130 may serve as a passage for emitting heat produced from the PCB part 110, and the extension part 130e of the metal core 130 may serve as a passage for emitting heat produced from the memory parts 120.

The semiconductor memory module of the present invention may have an additional objective of increasing a memory storage capacity. That is, as shown in FIGS. 2A-2C, the memory parts 120 can be mounted on both the first and the second surface of the PCB part 110, since an effective means of reducing operating temperatures is provided. In this case, the metal core 130 may include two metal cores that each respectively extend over the memory parts 120 mounted on the first and second surfaces of the PCB part 110. The description below relates to an exemplary embodiment of the semiconductor memory module using the two metal cores that cover the memory parts 120 mounted on the first and the second surface of the PCB part 110.

The PCB of the semiconductor memory module may include a PCB part 110 having a first surface and a second surface facing the first surface, and two metal cores 130 having insert parts 130i inserted inside the PCB part 110 and elongated extension parts 130e from one side of the PCB part 110. The two metal cores 130 may have a folding structure having at least one bent portion so that they may each cover the memory parts 120 mounted on the first and the second surfaces of the PCB part 110, respectively.

The insert parts 130i of the couple of the metal cores 130 may be configured to be included inside the PCB part 110. The extension parts 130e of the metal cores 130 may each have at least one bent portion so that they may be elongated from one side of the PCB part 110 to cover the memory parts 120 mounted on the PCB part 110. Accordingly, the metal cores 130 may serve as a passage for emitting heat produced from the operation of the semiconductor memory module. The insert parts 130i of the metal cores 130 may serve as a passage for emitting heat produced from the PCB part 110, and the extension parts 130e of the metal cores 130 may serve as a passage for emitting heat produced from the memory parts 120. Also, the efficiency of emitting heat may be improved by the extension parts 130e of the metal cores 130 having an additional bent part.

The memory parts 120 may be mounted on the surface of the PCB part 110 with mounting means 125. The memory parts 120 may be semiconductor memory chips or semiconductor memory packages. The mounting means 125 may be a combination of joining lands provided on the surface of the PCB and bonding pads of the memory parts 120.

Fixing means 135 may be provided between the memory parts 120 and the extension parts 130e of the metal cores 130. The fixing means 135 may be made of an adhesive material or a thermal interface material (TIM), which is a heat sink material having adhesiveness. The mechanical reliability of the semiconductor memory module may be improved when the adhesive material is used as the fixing means 135. However, the mechanical reliability and the thermal stability of the semiconductor memory module may both be improved when the heat sink material having adhesiveness is used as the fixing means 135. The heat sink material may consist of steel use stainless (SUS) or high carbon steel (SK5: carbon content of 0.82%).

When the PCB is inserted in a connector of a main board of an electronic circuit system such as a personal computer or a workstation, connector connecting pins 112 may be included. The connector connecting pins 112 may be provided on one edge for electrically connecting the memory module to the main board. The connector connecting pins 112 may be provided on the first surface and the second surface facing the first surface of the PCB part 110.

The heat produced during operation of the semiconductor memory module may be effectively emitted by applying the PCB to the semiconductor memory module, the PCB of which the PCB part and the metal core having the extension part elongated from the PCB part are coupled. Accordingly, lowering of the operation characteristics and reliability of the semiconductor memory module may be prevented.

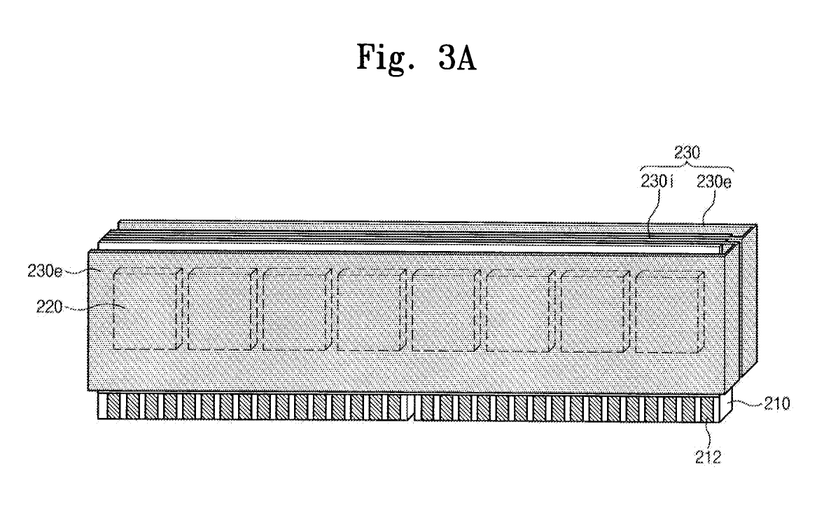

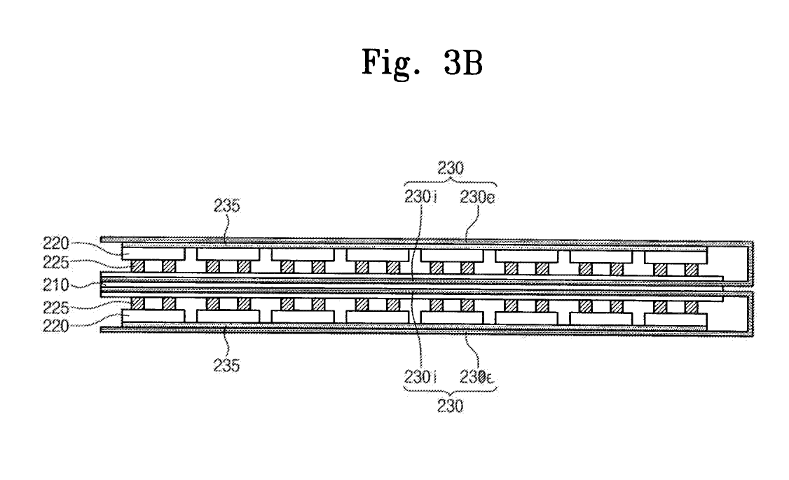

FIG. 3A is a perspective view of a semiconductor memory module according to another exemplary embodiment of the present invention, and FIG. 3B and FIG. 3C are a top plan view and a side view of FIG. 3A, respectively.

Referring to FIG. 3A to FIG. 3C, the semiconductor memory module may include a printed circuit board (PCB) and memory parts.

The PCB may include a PCB part 210 having a first surface and a second surface facing the first surface, and a metal core 230 having an insert part 230i inserted inside the PCB part 210 and an elongated extension part 230e extending from one side of the PCB part 210. As illustrated in FIG. 3A, the elongated extension part 230e may extend from a side of the PCB part 210 is the long axis direction. The extension part 230e of the metal core 230 may have a folding structure having at least one bent portion so that the extension part 230e substantially covers the memory parts 220. Thus, the extension part 230e of the metal core 230 may be elongated from one side of the PCB part 210 in the long axis direction and include a bent structure so as to be folded over and substantially cover the memory parts 220.

The PCB part 210 may be a rigid PCB or a flexible PCB. The metal core 230 may include thermal conductive material. The thermal conductive material may include one or more materials selected from a group consisting of aluminum, copper, silver and gold. However, the thermal conductive material may also include various other materials known in the art that either aid in the thermal conducting or aid in the structural integrity of the metal core 230. The metal core 230 may act as a heat sink whereby it serves as a passage for emitting heat produced during the operation of the semiconductor memory module. That is, since high operating temperatures reduce the performance of the memory parts 220 in a memory module as well as affecting the overall performance of the memory module, it is desirable to remove at least some of the heat produced during operation of the memory module away from the memory parts 220 and memory module to prevent the operating temperatures from drastically increasing and thereby reducing the overall performance of the memory module. In this embodiment of the present invention, the insert part 230i of the metal core 230 may serve as a passage for emitting heat produced from the PCB part 210, and the extension part 230e of the metal core 230 may serve as a passage for emitting heat produced from the memory parts 220. Also, the efficiency of emitting heat may be improved by the extension part 230e of the metal core 230 having an additional bent portion.

The semiconductor memory module of the present invention may have an additional objective of increasing a memory storage capacity. That is, as shown in FIGS. 3A-3C, the memory parts 220 can be mounted on both the first and the second surface of the PCB part 210, since an effective means of reducing operating temperatures is provided. In this case, the metal core 230 may include two metal cores that each respectively extend over the memory parts 220 mounted on the first and second surfaces of the PCB 210. The description below relates to an exemplary embodiment of the semiconductor memory module using the two metal cores that cover the memory parts 220 mounted on the first and the second surface of the PCB part 210.

The PCB of the semiconductor memory module may include a PCB part 210 having a first surface and a second surface facing the first surface, and two metal cores 230 having insert parts 230i inserted inside the PCB part 210 and elongated extension parts 230e from one side of the PCB part 210, in the long axis direction. The two metal cores 230 may have a folding structure having at least one bent portion so that they may each cover the memory parts 220 mounted on the first and the second surfaces of the PCB part 210, respectively.

The insert parts 230i of the two metal cores 230 may be configured to be included inside the PCB part 210. The extension parts 230e may have at least one bent portion so that it may be elongated from one side of the PCB part 210 to cover the memory parts 220 mounted on the PCB part 210.

The memory parts 220 may be mounted on the surface of the PCB with mounting means 225. The memory parts 220 may be semiconductor memory chips or semiconductor memory packages. The mounting means 225 may be a combination of joining lands provided on the surface of the PCB and bonding pads of the memory parts 220.

Fixing means 235 may be provided between the memory parts 220 and the extension parts 230e of the metal cores 230. The fixing means 235 may be made of an adhesive material or a thermal interface material (TIM), which is a heat sink material having adhesiveness. The mechanical reliability of the semiconductor memory module may be improved when the adhesive material is used as the fixing means 235. However, the mechanical reliability and the thermal stability of the semiconductor memory module may both be improved when the heat sink material having adhesiveness is used as the fixing means 235. The heat sink material may consist of steel use stainless or high carbon steel.

When the PCB is inserted in a connector of a main board of an electronic circuit system such as a personal computer or a workstation, connector connecting pins 212 may be included. The connector connecting pins 212 may be provided on one edge for electrically connecting the memory module to the main board. The connector connecting pins 212 may be provided on the first surface and the second surface facing the first surface of the PCB part 210.

The heat produced during operation of the semiconductor memory module may be effectively emitted by applying the PCB to the semiconductor memory module, the PCB of which the PCB part and the metal core having the extension part elongated from the PCB part are coupled. Accordingly, lowering of the operation characteristics and reliability of the semiconductor memory module may be prevented.

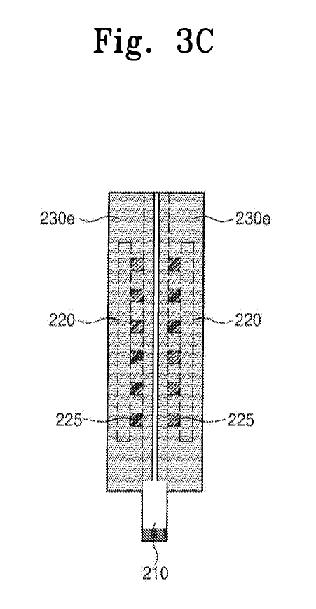

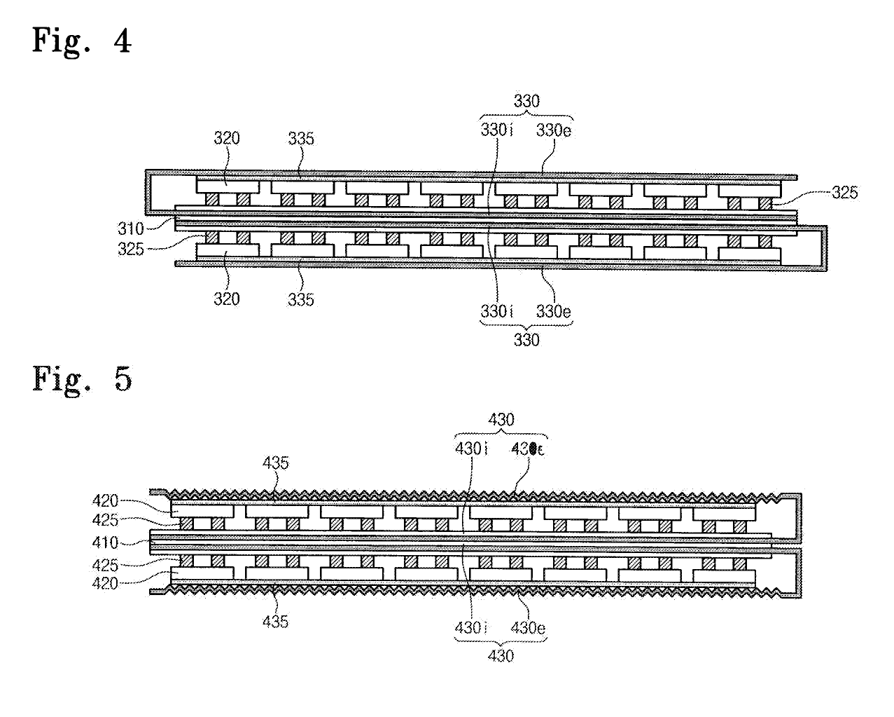

FIGS. 4 to 8 are side views of semiconductor memory modules according to other exemplary embodiments of the present invention.

As mentioned above, one of the advantages of the semiconductor memory module embodiments of the present invention is that they may allow for an increase in memory storage capacity. In the embodiments illustrated in FIGS. 4 to 8, the case where the memory parts are mounted on both a first and a second surface of a printed circuit board part, and where the metal core includes two metal cores is used. That is, the description below relates to exemplary embodiments of the semiconductor memory module using the two metal cores that cover the memory parts mounted on the first and the second surface of the printed circuit board part. However, other embodiments using the principles illustrated in FIGS. 4 to 8 may be applied using different memory module and metal core configurations.

Referring to FIG. 4, a printed circuit board (PCB) of a semiconductor memory module may include an extension part 330e of the metal cores 330 are elongated from opposite sides of the PCB part 310.

In more detail, the PCB of the semiconductor memory module may include the PCB part 310 having a first surface and a second surface facing the first surface, and metal cores 330 having insert parts 330i inserted inside the PCB part 310 and elongated extension parts 330e extending from opposite sides of the PCB part 310, in the long axis direction. The two metal cores 330 may have a folding structure including at least one bent portion so that they may each substantially cover the memory parts 320 mounted on the first and the second surfaces of the PCB part 310, respectively. However, in other embodiments, the elongated extension parts 330e may extend from opposite sides of the PCB part 310 in the short axis direction.

The insert parts 330i of the metal cores 330 may be configured to be included inside the PCB part 310. The extension parts 330e may have at least one bent portion so that it may be elongated from both sides of the PCB part 310 to substantially cover the memory parts 320 mounted on the PCB part 310.

The memory parts 320 may be mounted on the surfaces of the PCB part 310 with mounting means 325. The memory parts 320 may be semiconductor memory chips or semiconductor memory packages. The mounting means 325 may be a combination of joining lands provided on the surface of the PCB and bonding pads of the memory parts 320.

Fixing means 335 may be provided between the memory parts 320 and the extension parts 330e of the couple of the metal cores 330. The fixing means 335 may be made of an adhesive material or a thermal interface material (TIM), which is a heat sink material having adhesiveness. The mechanical reliability of the semiconductor memory module may be improved when the adhesive material is used as the fixing means 335. However, the mechanical reliability and the thermal stability of the semiconductor memory module may both be improved when the heat sink material having adhesiveness is used as the fixing means 335. The heat sink material may consist of steel use stainless or high carbon steel.

The heat produced during operation of the semiconductor memory module may be effectively emitted by applying the PCB to the semiconductor memory module, the PCB of which the PCB part and the metal core having an extension part elongated from the PCB part are coupled. Accordingly, lowering of the operation characteristics and reliability of the semiconductor memory module may be prevented.

Referring to FIG. 5, a printed circuit board (PCB) of a semiconductor memory module may have a structure where the extension parts 430e of the metal cores 430 are elongated from one side of a PCB part 410. However, the extension parts 430e of the metal cores 430 may be elongated from opposite sides of the PCB part 410 in other embodiments.

The PCB of the semiconductor memory module may include the PCB part 410 having a first surface and a second surface facing the first surface, and the metal cores 430 having insert parts 430i inserted inside the PCB part 410 and the extension parts 430e elongated from one side of the PCB part 410. The metal cores 430 may have a folding structure including at least one bent portion so that they may each substantially cover memory parts 420 mounted on the first and the second surfaces of the PCB part 410, respectively.

The insert parts 430i of the metal cores 430 may be configured to be included inside the PCB part 410. The extension parts 430e of the metal cores 430 may include at least one bent portion so that they may be elongated from one side of the PCB part 410 to substantially cover the memory parts 420 mounted on the PCB part 410. Also, the surface of the extension parts 430e of the metal cores 430, and in particular, the surface of the portion covering the memory parts 420 mounted on the PCB part 410, may be saw-blade shaped. This surface configuration of the extension parts 430e of the metal cores 430 may increase the surface area of the metal cores 430. Accordingly, the efficiency of emitting heat of the metal cores 430 may be improved.

The memory parts 420 may be mounted on the surface of the PCB part 410 with mounting means 425. The memory parts 420 may be semiconductor memory chips or semiconductor memory packages. The mounting means 425 may be a combination of joining lands provided on the surface of the PCB where bonding pads of the memory parts 420.

Fixing means 435 may be provided between the memory parts 420 and the extension parts 430e of the metal cores 430. The fixing means 435 may be made of an adhesive material or a thermal interface material (TIM), which is heat sink material having adhesiveness. The mechanical reliability of the semiconductor memory module may be improved when the adhesive material is used as the fixing means 435. Also, the mechanical reliability and the thermal stability of the semiconductor memory module may both be improved when the heat sink material having adhesiveness is used as the fixing means 435. The heat sink material may consist of steel use stainless or high carbon steel.

The heat produced during operation of the semiconductor memory module may be effectively emitted by applying the PCB to the semiconductor memory module, the PCB of which the PCB part and the metal core having an extension part elongated from the PCB part are coupled. Accordingly, lowering of the operation characteristics and reliability of the semiconductor memory module may be prevented.

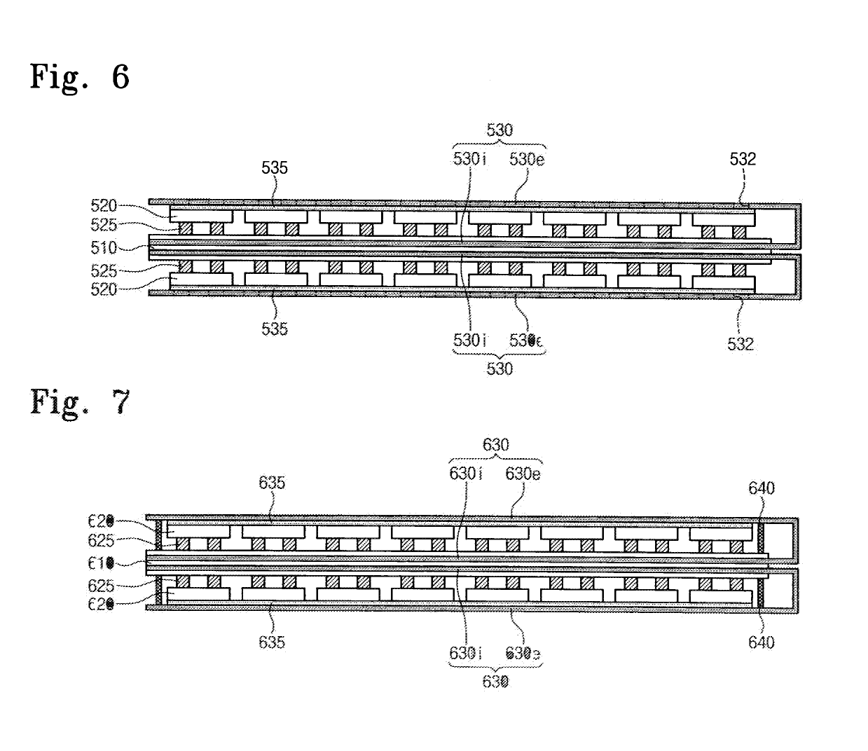

Referring to FIG. 6, a printed circuit board (PCB) of a semiconductor memory module may have a structure where the extension parts 530e of the metal cores 530 are elongated from one side of a PCB part 510. However, the extension parts 530e of the metal cores 530 may be elongated from opposite sides of the PCB part 510 in other embodiments.

The PCB of the semiconductor memory module may include the PCB part 510 having a first surface and a second surface facing the first surface, and the metal cores 530 having insert parts 530i inserted inside the PCB part 510 and the extension parts 530e elongated from one side of the PCB part 510. The metal cores 530 may have a folding structure including at least one bent portion so that they may each substantially cover memory parts 520 mounted on the first and the second surfaces of the PCB part 510, respectively.

The insert parts 530i of the metal cores 530 may be configured to be included inside the PCB part 510. The extension parts 530e of the metal cores 530 may include at least one bent portion so that it may be elongated from one side of the PCB part 510 to substantially cover the memory parts 520 mounted on the PCB part 510. Also, the surface of the extension parts 530e of the metal cores 530, and particularly the surface of the portions covering the memory parts 520 mounted on the PCB part 510, may have holes 532 punched through it. This surface configuration of the extension parts 530e of the metal cores 530 may increase the surface area of the metal cores 530. Accordingly, the efficiency of emitting heat of the metal cores 530 may be improved.

The memory parts 520 may be mounted on the surface of the PCB part 510 with mounting means 525. The memory parts 520 may be semiconductor memory chips or semiconductor memory packages. The mounting means 525 may be a combination of joining lands provided on the surface of the PCB and bonding pads of the memory parts 520.

Fixing means 535 may be provided between the memory parts 520 and the extension parts 530e of the metal cores 530. The fixing means 535 may be made of an adhesive material or a thermal interface material (TIM), which is heat sink material having adhesiveness. The mechanical reliability of the semiconductor memory module may be improved when the adhesive material is used as the fixing means 535. Also, the mechanical reliability and the thermal stability of semiconductor memory module may both be improved when the heat sink material having adhesiveness is used as the fixing means 535. The heat sink material may consist of steel use stainless or high carbon steel.

The heat produced during operation of the semiconductor memory module may be effectively emitted by applying the PCB to the semiconductor memory module, the PCB of which the PCB part and the metal core having an extension part elongated from the PCB part are coupled. Accordingly, lowering of the operation characteristics and reliability of the semiconductor memory module may be prevented.

Referring to FIG. 7, a printed circuit board (PCB) of a semiconductor memory module may have a structure where the extension parts 630e of the metal cores 630 are elongated from one side of the PCB part 610. However, the extension parts 630e of the metal cores 630 may be elongated from opposite sides of the PCB part 610 in other embodiments.

The PCB of the semiconductor memory module may include the PCB part 610 having a first surface and a second surface facing the first surface, and the metal cores 630 having insert parts 630i inserted inside the PCB part 610 and the extension parts 630e elongated from one side of the PCB part 610. The metal cores 630 may have a folding structure having at least one bent portion so that they may each substantially cover the memory parts 620 mounted on the first and the second surfaces of the PCB part 610, respectively.

The insert parts 630i of the metal cores 630 may be configured to be included inside the PCB part 610. The extension parts 630e of the metal cores 630 may include at least one bent portion so that it may be elongated from one side of the PCB part 610 to substantially cover the memory parts 620 mounted on the PCB part 610.

The memory parts 620 may be mounted on the surface of the PCB part 610 with mounting means 625. The memory parts 620 may be semiconductor memory chips or semiconductor memory packages. The mounting means 625 may be a combination of joining lands provided on the surface of the PCB and bonding pads of the memory parts 620.

Fixing means 635 may be provided between the memory parts 620 and the extension parts 630e of the metal cores 630. The fixing means 635 may be made of an adhesive material or a thermal interface material (TIM), which is a heat sink material having adhesiveness. The mechanical reliability of the semiconductor memory module may be improved when the adhesive material is used as the fixing means 635. However, the mechanical reliability and the thermal stability of semiconductor memory module may both be improved when the heat sink material having adhesiveness is used as the fixing means 635. The heat sink material may consist of steel use stainless or high carbon steel.

Internal support means 640 may be provided between the PCB part 610 and the extension parts 630e of the couple of the metal cores 630. The internal support means 640 may be pin-shaped. The pin-shaped internal support means 640 may be provided between the PCB part 610 and the extension parts 630e of the couple of the metal cores 630, except for the area where the memory parts 620 are mounted. The internal support means 640 may improve mechanical reliability of the semiconductor memory module.

The heat produced during operation of the semiconductor memory module may be effectively emitted by applying the PCB to the semiconductor memory module, the PCB of which the PCB part and the metal core having an extension part elongated from the PCB part are coupled. Accordingly, lowering of the operation characteristics and reliability of the semiconductor memory module may be prevented.

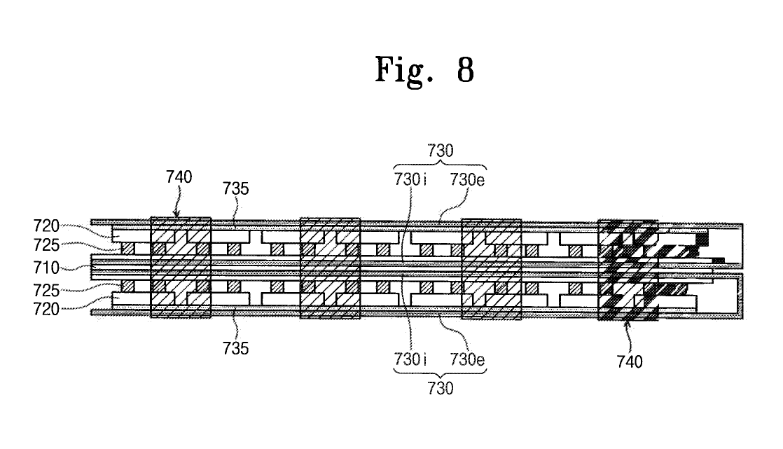

Referring to FIG. 8, a printed circuit board (PCB) of a semiconductor memory module may have a structure where the extension parts 730e of the metal cores 730 are elongated from one side of a PCB part 710. However, the extension parts 730e of the metal cores 730 may be elongated from opposite sides of the PCB part 710 in other embodiments.

The PCB of the semiconductor memory module may include the PCB part 710 having a first surface and a second surface facing the first surface, and the metal cores 730 having insert parts 730i inserted inside the PCB part 710 and the extension parts 730e elongated from one side of the PCB part 710. The metal cores 730 may have a folding structure having at least one bent portion so that they may each substantially cover the memory parts 720 mounted on the first and the second surfaces of the PCB part 710, respectively.

The insert parts 730i of the metal cores 730 may be configured to be included inside the PCB part 710. The extension parts 730e of the metal cores 730 may include at least one bent portion so that it may be elongated from one side of the PCB part 710 to substantially cover the memory parts 720 mounted on the PCB part 710.

The memory parts 720 may be mounted on the surface of the PCB part 710 with mounting means 725. The memory parts 720 may be semiconductor memory chips or semiconductor memory packages. The mounting means 725 may be a combination of joining lands provided on the surface of the PCB and bonding pads of the memory parts 720.

Fixing means 735 may be provided between the memory parts 720 and the extension parts 730e of the couple of the metal cores 730. The fixing means 735 may be made of an adhesive material or a thermal interface material (TIM), which is heat sink material having adhesiveness. The mechanical reliability of the semiconductor memory module may be improved when the adhesive material is used as the fixing means 735. However, the mechanical reliability and the thermal stability of semiconductor memory module may both be improved when the heat sink material having adhesiveness is used as the fixing means 635. The heat sink material may consist of steel use stainless or high carbon steel.

In this embodiment, external support means 740 are formed to surround at least a portion of the side of the PCB part 710. The external support means 740 is provided on the exterior of the PCB part 710 and the extension parts 730e of the metal cores 730, and hence, covers portions of the PCB part 710 and metal cores 730. The external support means 740 may be clip-shaped. The clip-shaped external support means 740 may surround the couple of the metal cores 730 in part, or be configured to cover the entire surface of the metal cores 730. The external support means 740 may improve the mechanical reliability of the semiconductor memory module.

The heat produced during operation of the semiconductor memory module may be effectively emitted by applying the PCB to the semiconductor memory module, the PCB of which the PCB part and the metal core having an extension part elongated from the PCB part are coupled. Accordingly, lowering of the operation characteristics and reliability of the semiconductor memory module may be prevented.

The semiconductor memory module according to embodiments of the present invention has a structure that mounts the memory parts to a printed circuit board (PCB) that includes a PCB part and a metal core having an extension part elongated from the PCB part. Apart from conventional structure, this structure enables heat produced from the operation of the semiconductor memory module to be effectively emitted. Accordingly, the PCB of these embodiments is able to prevent the lowering of the operation characteristics and reliability of the semiconductor memory module.

Although the present invention has been described in connection with the embodiment of the present invention illustrated in the accompanying drawings, it is not limited thereto. It will be apparent to those skilled in the art that various substitution, modifications and changes may be thereto without departing from the scope and spirit of the invention.

What is claimed is:

1. A printed circuit board comprising:
a printed circuit board part having a first surface and a second surface facing the first surface; and
a metal core including an insert part inserted inside the printed circuit board part and including an extension part elongated from at least one side of the printed circuit board part,
wherein the metal core has a folding structure having at least one bent portion.

2. The printed circuit board of claim 1, wherein the metal core includes two metal cores, each of the metal cores including an insert part and an extension part.

3. The printed circuit board of claim 2, wherein the extension parts of the two metal cores are respectively elongated from opposite sides of the printed circuit board part to face each other.

4. The printed circuit board of claim 1, wherein the metal core comprises a thermal conductive material.

5. The printed circuit board of claim 4, wherein the thermal conductive material comprises at least one selected from a group of aluminum, copper, silver, or gold.

6. The printed circuit board of claim 1 wherein the extension part has a saw blade-shaped surface.

7. The printed circuit board of claim 1, wherein the extension part includes at least one hole.

8. The printed circuit board is claim 1, wherein the printed circuit board part further comprises connector connecting pins provided on at least one surface of one selected between the first surface and the second surface.

9. A semiconductor memory module comprising:
a printed circuit board comprising a printed circuit board part having a first surface and a second surface facing the first surface, and a metal core having an insert part inserted inside the printed circuit board part and an extension part elongated from at least one side of the printed circuit board; and
memory parts mounted on the printed circuit board,
wherein the metal core has a folding structure having at least one bent portion to substantially cover the memory parts.

10. The semiconductor memory module of claim 9, wherein the memory parts are mounted on the first surface and the second surface of the printed circuit board.

11. The semiconductor memory module of claim 9, wherein the metal core includes two metal cores, each of the metal cores including an insert part and an extension part.

12. The semiconductor memory module of claim 11, wherein the extension parts of the two metal cores are elongated from opposite sides of the printed circuit board part to face each other.

13. The semiconductor memory module of claim 9, further comprising mounting means provided between the printed circuit board and the memory parts.

14. The semiconductor memory module of claim 9, wherein the metal core comprises a thermal conductive material.

15. The semiconductor memory module of claim 14, wherein the thermal conductive material comprises one selected from a group of aluminum, copper, silver, or gold.

16. The semiconductor memory module of claim 9, wherein the extension part has a saw blade-shaped surface.

17. The semiconductor memory module of claim 9, wherein the extension part includes at least one hole.

18. The semiconductor memory module of claim 9, further comprising fixing means provided between the memory parts and the extension part.

19. The semiconductor memory module of claim 18, wherein the fixing means includes an adhesive material or a heat sink material having adhesiveness.

20. The semiconductor memory module of claim 9, further comprising internal supporting means provided between the printed circuit board and the extension part.

21. The semiconductor memory module of claim 9, further comprising external supporting means surrounding at least a portion of the printed circuit board, the external supporting means covering at least a portion of the printed circuit board part and the extension part.
